(19) United States
(12) Patent Application Publication
(10) Pub. No.: US 2003/0081698 A1
(43) Pub. Date: May 1, 2003

(54) Method of conversion and converter of frequency modulated signal into pulse frequency Modulated signal with suppression of carrier frequency components of the pulse frequency modulation

(76) Inventor: Vadim Minuhin, Bloomington, MN (US)

Correspondence Address: Vadim Minuhin, 8709 Lakeview Circle, Bloomington, MN, 55438-1533, US

(21) Appl. No.: 09/953,595

(22) Filed: Sep. 17, 2001

(51) Int. Cl. H03C 7/00; H03D 1/24; H04L 7/00

(52) U.S. Cl. 375/321; 375/315; 375/356

(57) ABSTRACT

Analog video tape recording (VTR) and video cassette recording (VCR) systems/apparatuses with novel converter of a frequency modulated signal into the pulse-frequency-modulated (PFM) signal during readback are described. The novel converter provides effective filtering function in itself and suppresses all carrier harmonics of the PFM signal. This reduces combination noise at the input to the PFM filter-demodulator by 20-25 db. Therefore, filtering requirements to PFM demodulator are greatly reduced and it can be of very simple design. The novel converter provides significant improvement in performance and reduces cost of analog VTR/VCRs.

### CROSS-REFERENCE TO RELATED APPLICATIONS.

(NOT APPLICABLE)

### STATEMENT REGARDING FEDERALLY SPONSORED RESEARCH OR DEVELOPMENT.

(NOT APPLICABLE)

### REFRENCE TO FILES PROVIDED IN ATTACHMENTS

The subject of this invention can not be understood without detailed deliberation on analog pulse modulation (APM) theory, because the invention is based on that theory. Unfortunately, English (and Japanese) publications on this subject are highly disappointing and contain many errors and missing pieces. In particular, the theory of pulse frequency modulation (PFM) that is utilized in every analog video tape recorder (VTR) and consumer videocassette recorder (VCR) is not available in English at all. Surprisingly, video recording industry professionals in the U.S.A. (and Japan) erroneously believe that they work with an ordinary frequency modulation (FM). Furthermore, they do not realize that VTR/VCRs employ FM to PFM converter and these apparatuses are working during readback with the PFM-modulated signal. This anomaly can be illustrated by the recently published tutorial on VTR/VCRs technology:

Hiroshi Sugaya. “Analog Video Recording”. Chapter 5 in the book “Magnetic Storage Handbook”, C. D. Mee and E. D. Daniel, editors, McGraw-Hill, 1996.

Many fine technological details are described in this (105 pages long) tutorial. However, with respect to modulation, the tutorial refers everywhere to FM, instead of PFM, including the readback.

The confusion between PFM and FM among video recording professionals hurts both video recording industry and consumers because it results in inferior design of commercial VTR/VCRs with respect to performance and cost.

Before application for this patent it was necessary to develop correct pulse position modulation (PPM) and PFM theories—otherwise, operations and novelty of the invention could not be understood. These theories have been published recently in two papers:

1. V. B. Minuhin. “Modulation Noise in Thin-Film Metallic Media: Elements of Pulse/Transition Modulation Theory.” IEEE Transactions on Magnetics, Vol. 36, No. 4, part II, July 2000.

2. V. B. Minuhin. “Modulation in Video Tape Recorders”, IEEE Transactions on Magnetics, vol. 36, No. 1, January, 2000.

The first paper explains dismal state and errors in the APM theory published in English; the second paper actually provides description of the prior art for the invention (on the level of the whole video recording system, for which hardware of the invention is just one block). These two papers together contain approximately 25 pages of printed text and can not be part of the printed patent.

For this application, related two papers are provided as attachments in the form of hard copies. They are also available on request by e-mail: vminuhin@hotmail.com as electronic files.

### BACKGROUND OF THE INVENTION

The field of the invention is the communication systems that employ FM. It is beneficial in some of these systems to convert FM to PFM before the final signal demodulation. Most obvious examples of such systems are systems with magnetic recording that utilize a conventional FM during recording cycle, in particularly VTR/VCRs and systems of instrumental recording. Both systems contain FM to PFM converter as a standard block, see, for example:

1. “Modern Instrumentation Tape Recording. An engineering handbook by EMI”, The Engineering Department, EMI Technology Inc. Library of Congress Catalog Card Number: 78-60084. 1978;

2. Mentioned above 2^{-nd} Minuhin's paper.

The best example of the Prior Art to the invention is the modulation-demodulation system in commercial VTR/VCRs. Actually, the invention was conceived after analyzing problems in these apparatuses. Presented below is a slightly modified copy of the second paper cited above. This work summarizes status and elucidates problems of modulation used in VTRs/VCRs. It is the only work published in English that explains internal working of VTRs/VCRs from the viewpoint of PFM theory. The paper eliminates confusion between FM and PFM modulation in these devices. As mentioned, the original text of this work is also provided as a separate attachment.

### Modulation in Video Tape Recorders (Prior Art)

### Vadim B. Minuhin, Senior Member, IEEE

The paper was published in January 2000 issue of IEEE Transactions of Magnetics. Below is a slightly modified version of the paper. The modification was made to comply with requirements for patent application. An additional figure (FIG. 2) is provided that illustrates the hardware of the prior art. References to hardware blocks and to corresponding numerals in FIG. 2 are inserted into the original text of the paper.

Abstract—This paper presents the theory of pulse-frequency modulation, used for signal transmission in analog video recorders. The paper demonstrates that signal processing in recorders is of the discrete-time type, with the sampling exceeding the Nyquist rate and with restoration of the analog video output from samples in the filter-demodulator.

Index Terms—Magnetic tape recording, video recording, frequency modulation, pulse frequency modulation, pulse position modulation

### I. Introduction

A recently published paper [1] on frequency modulation (FM) in video tape recorders (VTRs) does not address the demodulation process, which is essential for understanding signal processing in VTRs.

The pioneering work on signal processing in VTRs [2] was done at Ampex Corporation in the 1960's, when Ampex engineers had come up with an optimal, practical scheme for pulse frequency modulation (PFM). Since then PFM has been adopted for all analog VTRs and consumer videocassette recorders (VCRs) world-wide. However, authors of [2] had not realized that they had invented a near-optimal discrete-time machine with the PFM that samples analog video signal at the rate that only moderately exceeds Nyquist rate and restores continuous-time analog video output from samples in the filter-demodulator. This absence of cognizance occurred apparently for two reasons. First, [2] was written in hindsight and was an explanation of the working system that was created on the basis of engineering intuition rather than rigorous theory. Second, the comprehensive theory of analog pulse modulation was not available to the authors of [2], because it was published in English [3, 4] only after completion of author's work. Moreover, even in the published books [3,4] the theory of PFM was “missing”. In contrast, the PFM theory was published in Russia in the 1940's [5,6]. Russian engineers recognized immediately what was invented and adapted Ampex modulation scheme in Russian VTR/VCR's.

A confusion about signal processing in VTR/VCR's still exists today. For example, the sections on “video recording” in [7, 8] refer exclusively to FM modulation in VTR/VCR's, and only the table of the sampling rates for various VTR types in [8, p.24.84] reveals discrete-time signal processing.

### II. Signal processing in VTR/VCR's

In discussing signal processing here, we divert our attention from necessity to transmit various control and auxiliary signals for VTR synchronization and maintenance of a stable and satisfactory reproduced image. For conceptual simplicity, we assume here a “direct recording” of a composite broadcast video signal [8]. We also note that all VTR's employ rather unconventional FM, with a relatively small ratio of carrier frequency to modulating frequency band in order to maintain a reasonable expenditure of tape.

FIGS. 1 and 2 illustrate in principal terms the signal processing in VTR's for the case of a single tone (ST) PFM. Graph (a) on FIG. 1 represents the FM-modulated write current that is pumped into a winding of the recording head. During the playback cycle, due to differentiating nature of the readback head, zero-crossings in the write current create alternating polarity peaks at the head output—graph (b). The raw readback signal (b) is amplified is amplified in amplifier 1 and low-pass filtered in the noise-suppressing filter 2 and then hard limited in the limiter 3—see graph (c). For a ST FM modulating signal the spectrum of modulated and hard-limited wave (c) has been found in [9] by applying the theory of the pulse position modulation (PPM) [6] to the modulation of the square wave edges:

$$c ( t ) = \frac{4 A}{π} {\sum }_{m = 1 , 3 , 5 …}^{∞} {\sum }_{n = - ∞}^{∞} \frac{1}{m} {J}_{n} ( m Φ ) Sin ( {Ω}_{m , n} t + {ϕ}_{m , n} ) , \qquad ( 1 )$$

where

ω carrier frequency of FM;

Ω frequency of the ST modulation;

θ initial phase of that modulation;

Δω frequency deviation in modulation;

A amplitude of the square wave;

Φ=Δω/Ω index of modulation;

Jₙ(x) Bessel function of the first kind with integer index n;

Ω_{m,n}=mω+nΩ combination frequency;

φ_{m,n} combination phase that depends on both initial phases of carrier and modulating signal, and on both summation indexes: m and n.

Equation (1) is the “one-line comprehensive replacement” of Appendix 1 in [2].

Filtering out all harmonics except fundamental (m=1) in the hard limited FM signal (1) restores the original FM waveform, thereby greatly reducing the detrimental effects of noise and parasitic amplitude modulation in the channel before the signal is demodulated by conventional FM demodulators, as for example is done in FM radio. However, this is not the way the demodulation is done in the VTR's [2]. Instead, all VTR's convert an original FM to PFM. A hard limited signal (c) is supplied to the pulse forming circuit 4 that generates standardized pulses from both signal edges, as shown by graph (d). Thus, the output of the pulse circuit 4 is a sequence of pulses modulated in their frequency of repetition.

For a ST (Sin Ωt+θ) modulating signal, the pulse sequence (d) is described [6] by the equation:

$$d ( t ) = \frac{g ( 0 )}{T} + \frac{\vert g ( Ω ) \vert}{T} \cdot ϵ \cdot cos ( Ω t + {ϕ}_{0 , 1} ) + \frac{1}{π} {\sum }_{m = 1}^{∞} {\sum }_{n = - ∞}^{∞} \vert g ( {Ω}_{m , n} ) \vert \cdot \frac{{Ω}_{m , n}}{m} \cdot {J}_{n} ( m Φ ) \cdot cos ( {Ω}_{m , n} t + {ϕ}_{m , n} ) , \qquad ( 2 )$$

where

T period of the (unmodulated) pulse sequence;

ω=2π/T frequency of pulse repetition;

Ω_{m,n}=Mω+nΩ combination frequency;

g(Ω_{m,n}) complex spectral density of the standardized pulse at frequency Ω_{m,n};

Δω amplitude of deviation in pulse repetition rate;

Φ=Δω/Ω index of modulation;

ε=Δω/ω relative deviation in the pulse repetition rate;

φ_{m,n}=n·(θ−π/2)+arg[g(Ω_{m,n})]−mωt₀′ combination phase;

t₀′ time position of the first pulse [see graph (d)] relative to the time moment t=0.

The formula (2) is the “one-line and more comprehensive replacement” of Appendix 2 in [2].

Note, that the frequency of pulse repetition ω=2π/T in (2) is twice that of the original FM-wave, graph (a). That frequency is outside of a “head-tape pass-band” and is generated in readback electronics.

The second additive term in (2) is proportional to the relative deviation E in the pulse repetition rate and (see graphs in FIG. 1) is the exact copy of the original modulating signal, if g(Ω) is constant in the modulating frequency band. Practical approximation to this condition is achieved by employing short standardized pulses. It is these low-frequency information-bearing components of the spectra (2) that are utilized in VTR/VCR's for signal demodulation. Components of the double sum in (2) represent noise. The low frequency components are selected by the low-pass filter/demodulator 5, which blocks out components of the double sum. The demodulator 5 also has a compensating circuit that blocks undesired, strictly dc component caused by the dc component of the formed pulse sequence—first term in (2). The selected demodulated signal is shown on FIG. 1 schematically by the graph (e).

FIG. 14 of ref. [2] illustrates the achieved spectral separation (although with some residual overlapping) of the transmitted-received multi-frequency video-signal from the components of the double sum. It is shown in [2], how a relative small increase in the carrier/(modulation band) ratio reduces “the overlapping problem” to negligible level.

It is time now to point out that the very notion of the pulse modulation [3] means that in the VTR/VCR's channels we are dealing with discrete-time samples of an analog modulating signal. The pulse former 4 shown on FIG. 2 actually represents FM to PFM converter-sampler 6. The following signal processing is accomplished in the discrete-time domain. It is obvious from the comparison of formulae (1) and (2) and from FIG. 1, that there are at least two samples per period of even the highest frequency component in the video signal. Therefore, the Nyquist criterion is satisfied and the low-pass filter-demodulator 5 restores a continuous-time analog video signal from sampled values, albeit these sampled values contain some distortions. As mentioned, a part of them may be caused by residual overlapping of useful and noise (double sum) spectrums if inappropriate modulation parameters are chosen. We will focus briefly on other distortion types.

A small ratio of carrier/(modulation band) in the original recording modulation (graph (a)) causes partial “trespassing” of low frequency FM side-band into the negative frequency region. “Trespassed” components physically fold back into the positive frequency region with the wrong frequencies and phases, and produce spurious phase modulation. These “Folding Spectrum” distortions have been discussed and analyzed in [2] and [10]. It was found that by correct choice of modulation parameters, parasitic modulation caused by folding components can be reduced to ˜20-40 db below the intentional modulation, depending on the degree of compromise in an increase of the carrier/(modulation band) ratio.

During readback, transitions in magnetization (graph (a)) are transformed into signal peaks—graph (b). Therefore, zero-crossings in readback are determined not by the original zero-crossings in the modulated write current, but by the intersymbol interference between neighboring peaks at the output of the readback channel, which has large magnitude variations in its wavelength response. This, no doubt, causes additional distortions in the sampled values. Also, the presence of additive noise in readback shifts, i.e. harmfully modifies sampled values. Both these impairments are dependent on the transfer function of the reproducing channel. They were analyzed in several (translated) Russian papers [11-14], which resulted in a conclusion of significant benefits of PFM versus conventional FM.

In summary, whatever zero-crossing distortions occur in the PFM discrete-time sampling channel, it works, albeit with some degradation of video signal quality. Commercial VTRs and VCRs are results of many engineering compromises between performance, channel complexity and cost.

### Appendix (to this copy of paper only): Elements of The Pulse Frequency Modulation Theory

The present author is not aware of any English publication with a comprehensive treatment of the PFM. There exists a short section on PFM in the Panter's book [15], but the results there are incorrect; the same erroneous results are repeated in [7].

In reality, PFM and PPM exist simultaneously: occurrence of the one automatically means occurrence of the other. To prove validity of the main equation (2), we have to start with the ST PPM, because formula (2) for the PFM was obtained in [6] as a particular case of the PPM.

There are two different kinds of PPM [3]; one is with uniform sampling, the other is with natural sampling. Only the later leads to meaningful intentional PFM modulation. In general, the PPM (with both sampling types) is described by the discrete-time equation:

tₖ+Δtₖ=kT+t₀, k=−∞. . . ,−1, 0, 1, 2, . . . ∞, (3)

where k is the pulse number in the infinite pulse sequence, tₖ is the moment of generation of that pulse, Δtₖ is the time shift of that pulse due to modulation, T is the period of pulse repetition and t₀ is the (arbitrary) constant—position of 0^{-th} (unmodulated) pulse in the sequence—see graph (d). For a ST modulation of frequency Ω and with the initial phase θ, the defining discrete-time equation for natural sampling is:

Δtₖ=Δt·Sin (Ωtₖ+θ), (4)

where Δt is the amplitude (maximal value) of the ST modulating shift. Combining (3) and (4) yields the discrete-time equation of the ST PPM with natural sampling:

tₖ+Δt·Sin (Ωtₖ+θ)=kT+t₀. (5)

After lengthy derivations in [6], based on equation (5), the Shirman's expression for a ST PPM comes to:

$$\frac{E ( t ) = \frac{g ( 0 )}{T} + \vert g ( Ω \vert}{T} \cdot Ω \cdot Δ t \cdot cos ( Ω t + {ϕ}_{0 , 1} ) + \frac{1}{π} {\sum }_{m = 1}^{∞} {\sum }_{n = - ∞}^{∞} \vert g ( {Ω}_{m , n} ) \vert \cdot \frac{{Ω}_{m , n}}{m} \cdot {J}_{n} ( m Φ ) cos ( {Ω}_{m , n} t + {ϕ}_{m , n} ) . \qquad ( 6 )$$

Notation here is the same as in (2), but the argument of the Bessel function is mΦ, where Φ=2πt/T is the index of the PPM modulation and φ_{m,n}=nθ+arg[g(Ω_{m,n})]−mωt₀.

All formulas presented so far are referred to the classified Russian monograph [6], which is inaccessible for the reader. We have to demonstrate validity of these formulas with reference to available publications. The most suitable publication in English, that contains derivations for a ST PPM with natural sampling is the book [4]. However, Bennett's derivations in that book contain an oversight, which, fortunately, is easy to spot and correct. The examination of pages 249-250 of [4] shows that the equation (6-2-1) for the sweep voltage V(t) that generates PPM waveform should read

$$V ( t ) = \frac{P}{T} ( t - r T ) , \text{not} V ( t ) = \frac{2 P}{T} ( t - r T ) .$$

Furthermore, the operation of Bennett's hypothetical hardware is independent of the sweep ramp slope (zero threshold for pulse generation). Therefore, the voltage P may have an arbitrary value and it should not be present in the final Bennett's formula (dimensional analysis also confirms this). Assuming for convenience unit ramp slope, i. e. P=T, an erroneous P should be replaced by T/2 and the corrected Bennett's equation (6-2-15) for the ST PPM should read:

$$E ( t ) = \frac{P}{2 π} A ( 0 ) - \frac{q Q}{T} A ( q ) \cdot sin [ q t + B ( q ) ] + {\sum }_{m = 1}^{∞} {\sum }_{n = - ∞}^{∞} \frac{m p + nq}{m π} \cdot {J}_{n} ( \frac{m 2 π Q}{T} ) . \\ A ( m p + nq ) \cdot cos [ ( m p + nq ) t + B ( m p + n q ) + \frac{n π}{2} ] . \qquad ( 7 )$$

The correspondence between notations used in (6) and (7) are [4]: ω=p, Ω=q, Δt=Q, |g(·)|=A(·), arg[g(·)]=B(·). Assuming in (6) θ=π/2 and t₀=0 and replacing symbols in (4)-(6) by the Bennett's symbols yields formula (7). Thus, Bennett's equation (7) is the particular case of Shirman's equation (6) for parameters of modulation θ=π/2 and t₀=0. The validity of equation (6) has been proved.

Finally we will draw the parallel between PPM and PFM.

An equation of the FM-modulated sinusoidal wave υ_{FM}(t), graph (b) in FIG. 1 is

υ_{FM}(t)=A·Sin [ωt+φ(t)], (8)

where φ(t) is the variable phase caused by modulation.

The instantaneous frequency of the wave, according to definition will be:

$$\frac{ⅆ [ ω t + ϕ ( t ) ]}{ⅆ t} = ω + \frac{ⅆ [ ϕ ( t ) ]}{ⅆ t} , \qquad ( 9 )$$

where the second term at the right-hand-side represents a variable component of the frequency caused by the modulation. This component is proportional to the FM-modulating voltage υ_{mod}(t), i.e.:

$$\frac{ⅆ [ ϕ ( t ) ]}{ⅆ t} = {K}_{MOD} \cdot {v}_{mod} ( t ) , \qquad ( 10 )$$

where K_{MOD} is the transfer coefficient of the modulator, Radians/(sec·volts). Integrating (10) yields

$$ϕ ( t ) = {K}_{MOD} {\int }_{0}^{t} {v}_{mod} ( t ) ⅆ t + {ϕ}_{0} , \qquad ( 11 )$$

where φ₀=(t)|ₜ₌₀. Substituting (11) into (8) yields

$${v}_{F M} ( t ) = A \cdot Sin [ ω t + {K}_{MOD} {\int }_{0}^{t} {v}_{mod} ( t ) ⅆ t + {ϕ}_{0} ] . \qquad ( 12 )$$

The zero-crossing events in (12) that correspond to rising portions of FM-wave satisfy equation

$$ω {t}_{k} + {K}_{MOD} {\int }_{0}^{{t}_{k}} {v}_{mod} ( t ) ⅆ t + {ϕ}_{0} = 2 π k , \qquad ( 13 )$$

where k is any integer. Dividing (13) by ω yields

$${t}_{k} + \frac{{K}_{MOD}}{ω} {\int }_{0}^{{t}_{k}} {v}_{mod} ( t ) ⅆ t = k T + {t}_{0} , \qquad ( 14 )$$

where t₀=(−φ₀)/ω.

For a ST modulation:

υ_{mod}(t)=V_{MOD} Sin (Ωt+θ) (15)

and the equation (14) for pulses generated from raising portions of FM wave takes the discrete-time form:

tₖ+Δt Sin (Ωtₖ+θ−π/2)=kT+t₀′, (16)

where

t₀′=t₀−Δt Cos θ (17)

and

$$Δ t = \frac{{K}_{MOD} {V}_{MOD}}{ω Ω} = \frac{1}{Ω} \cdot \frac{Δ ω}{ω} = \frac{ϵ}{Ω} , \qquad ( 18 )$$

Δω being the deviation of the pulse repetition rate, and E being the relative frequency deviation.

Now, substituting (18) into (6) we transform the equation (6) for the ST PPM into the equation (2) for the ST PFM, thereby confirming the validity of equation (2).

Furthermore, comparing equations (15)-(18) with the discrete-time equation (5) for the proper ST PPM leads us to the following conclusions:

1. For a ST modulating signal spectra of PPM and PFM modulations are exactly the same.

2. PFM can be considered as a particular case of the PPM, in which, for a ST modulation, maximal time shift of the pulses is determined by the formula (18) and is inversely proportional to the modulating frequency Ω.

3. The phase of the pulse shift in PFM differs from the phase of the modulating PPM signal by −π/2.

These conclusions are an indication of a signal integration in the PFM relative to the PPM. Therefore, the relations between PPM and PFM are the same as those between phase and frequency modulations in an angle modulation of a sinusoidal carrier: phase variations according to law ψ(t) lead to variation of instantaneous frequency as derivative of ψ(t); variations of instantaneous frequency according to law ω(t) lead to variation of phase as an integral from ω(t). Obviously, both PPM and PFM can be named Pulse Angle Modulations.

The derivations above were for zero-crossings caused by rising portions of the FM-wave. Obviously, the same derivations can be repeated for zero-crossings caused by falling portions of the FM-wave. Therefore, the described (and existing in reality) modulation-demodulation scheme (FIG. 2) can be considered as two parallel interleaved channels with standardized pulses generated from both zero-crossing types and supplied to a common filter-demodulator. Thus, FM carrier frequency is doubled (in the readback electronics), thereby sampling instantaneous frequency of the recorded FM wave (averaged over half-period of this wave) twice during each FM period, providing practical near-optimal discrete-time signal processing.

References to paper “Modulation in Video Tape Recorders (Prior Art)”

1. J. C. Mallinson. “Frequency Modulation in Video Tape Recorders”. IEEE Transactions on. Magnetics. V.34, No.6, November 1998, pp.3916-3921.

2. M. O. Felix, H. Walsh. “FM Systems of Exceptional Bandwidth”. Proceedings of The IEE (London), V.112, No.9, September 1965, pp.1659-1668.

3. H. E. Rowe. “Signals and Noise in Communication Systems”. D Van Nostrand Company, Inc. Princeton. 1965.

4. M. Schwartz, W. R. Bennett, S. Stein. “Communication System and Techniques”. McGraw-Hill, New York, 1965. Reprinted by IEEE Press in 1996.

5. Ya. D. Shirman. “Spectra of Time (Phase) and Frequency Pulse Modulation” (in Russian). Journal Radiotechnique, Vol.1, No.7-8, pp.52-76, 1946

6. V. I. Siforov, S. A. Drobov, Ya. D. Shirman, N. A. Zheleznov, “Theory of Pulse Radiocommunication”. A monograph In Russian. Classified limited print by Leningrad Military Air-Force Engineering Academy, 1951 (Declassified in 90^{-ties}).

7. D. G. Fink, D. Christiansen. “Electronics Engineers' Handbook”, Third Edition, McGraw-Hill, New York, 1989.

8. D. Christiansen. “Electronics Engineers' Handbook”, Fourth Edition, McGraw-Hill, New York, 1997.

9. V. B. Minuhin. “Noise Immunity of Magnetic Recording Systems”. Telecommunications and Radio Engineering, Part 2. V.22, No. 12, December 1967, pp.110-116.

10. V. E. Molodsov. “Analysis of Combination Distortion in the Pulse-Counter-Type Demodulator”. In Russian. Proceedings of Russian National Institute of Television and Radio Broadcasting.. V. 4(23), pp. 29-36, 1973.

11. V. I. Tsherbina. “Signal to Noise Ratio for FM with Low Frequency Carrier”. In Russian. Proceedings of Russian National Institute of Television and Radio Broadcasting. V.3(22), pp 57-65 1972.

12. L. S. Gordeyev. “Noise Immunity of Frequency Detection with Frequency Doubling in Magnetic-Recording Devices”. Telecommunucation and Radio Engineering. Part 2, Vol. 25, No.9, 1970, pp.122-125.

13. L. S. Gordeyev. “Transmission of an FM Signal Through a Magnetic Recording Channel”. Telecommunucation and Radio Engineering. Part 2, Vol.. 27, No.1, 1972. pp.119-120.

14. L. S. Gordeyev. “Signal Distortions in Magnetic Recording with Frequency Modulation”Telecommunucation and Radio Engineering. Part 2, Vol. 28, No.7, 1973. pp.107-110.

15. P. F. Panter. “Modulation, Noise and Spectral Analysis”. McGraw-Hill, New York, 1965.

This finishes the description of the prior art of the modulation-demodulation system used in analog VTR/VCRs.

These modulation-demodulation systems, however, have several practical deficiencies. The paper presented above concludes with the statement:

“Thus, FM carrier frequency is doubled (in the readback electronics), thereby sampling instantaneous frequency of the recorded FM wave (averaged over half-period of this wave) twice during each FM period, providing practical near-optimal discrete-time signal processing.”

This statement relates actually only to theoretically optimal signal processing, without considering problems of its practical implementation. One of the practical problem in the prior art is the inefficient FM to PFM converter-sampler, which substantially complicates and exacerbates process of separation of useful signal from the combination noise. As shown on FIG. 2, the FM to PFM converter of the prior art (numerals 6) consists of former of short standardized pulses 4, which is excited by the zero-crossings in the incoming FM-modulated signal. The short standardized pulses have a wide spectrum, which is a problem that had not been realized in the prior art.

In the description of prior art above, the references have been made to filtration in VTR/VCRs. What was stated there can be paraphrased as following:

The second additive term in the equation for the PFM modulated signal represents low-frequency information-bearing components of the spectra (2) that are utilized in VTR/VCRs for signal demodulation. Components of the double sum in (2) represent the “combination noise”, which must be suppressed. The low frequency components of (2) are selected by the linear low-pass filter-demodulator, which suppresses components of the double sum.

What was asserted in the last sentence is easier to say than to implement in practice. Due to unusually small ratio of carrier frequency to modulation band, obtaining required filtration in commercial VTR/VCRs represents challenge for the designers. This is because concept of ideally functioning, (brick-like) low-pass filter with ideal phase response in band-pass zone, and large attenuation in band-reject zone implicitly assumed in the description of the prior art is unrealistic. The low-pass filter-demodulator in VTR/VCRs of the prior art must suppress combination noise [double sum in (2)] that is two order of magnitude larger than the useful signal. Furthermore, frequencies of useful signal and combination noise are very close.

The FIG. 3 visually summarizes the PPM modulated signal that is “presented” to the filter-demodulator of (the prior art) VHS (video home system) VCRs. According to standards for VHS VCRs (given in the book “Electronic Engineers' Handbook”, D. Cristiansen, Editor, McGraw-HILL, New York, 1996, pages 24.81-24.91), the carrier frequency of FM modulation during recording cycle is 3.4 Mhz, and video signal bandwidth is 25 Hz -3 Mhz. As already explained, the conversion of FM to PFM in the readback cycle doubles carrier frequency. Thus, carrier frequency in readback becomes 6.8 Mhz, with the same modulation bandwidth as illustrated by FIG. 3.

It had been found practically long time ago that to avoid folding spectrum distortions during recording and to limit noise in readback requires compromise. The index of modulation Φ for the highest video signal frequency should be chosen in the range 0.2<Φ<0.25 (see for example, Felix&Walsh work in references to Minuhin's paper and the cited above Sugaya's tutorial).

FIG. 3 illustrates spectral content of the signal at the output of the FM to PFM converter of the prior art for the case of a single tone modulation with the frequency Ω=3 Mhz, index of modulation Φ=0.225 and the width of standardized rectangular pulse equal 10% of the pulse period. Spectral components are calculated according to formula (2). The magnitudes of components are shown together with their corresponding frequencies (at horizontal axis). The fundamental carrier harmonic (m=1) is at the frequency 6.8 Mhz. DC component is not shown. Note that components with frequencies 13.6, 10.6 and 7.6 Mhz correspond to double sum components with m=2. Only lower frequency side-band components for m=2 are shown.

The only useful video signal component is marked on FIG. 3 by the black bubble, numeral 7. As it is obvious, the useful signal is about 20 times smaller than the carrier component with m=1 and even smaller than the first order modulation side-band components for both m=1 and m=2 at frequencies 3.8, 9.8 and 10.6 Mhz. Thus, the useful signal is 27 db smaller than the combination noise. Rather sophisticated (and expensive) filter-demodulator (with a linear phase response in the pass-band zone) is required to separate such small useful signal from the overwhelming combination noise.

In reality, employment of short standardized pulses in FM to PFM converters-samplers of the prior art is a bad choice. The useful video signal [second additive term in (2)] is also proportional to the magnitude spectrum of the standardized pulse. This spectrum (for used short pulses) is shown on FIG. 3 (in arbitrary vertical scale) by the dashed line named “First spectral lobe of pulse-width filter”.

It will be shown in the following sections, that utilization of an optimal width of standardized pulses as an additional filter inside of the FM to PFM converters themselves provides very efficient (and inexpensive) filtration in VTR/VCRs and solves the “filtration problem” of the prior art.

### BRIEF SUMMARY OF THE INVENTION

The goal of the Invention is to provide better solution for the critical problem of filtration in the systems of the prior art. In these systems, the filter-demodulator had to select small useful signal and suppress huge combination noise that is sometimes 20-30 times larger in magnitude and close in frequencies to the useful signal. No practical filter of reasonable complexity and cost could do this job adequately in the commercial VTR/VCRs of the prior art and consequently these devices are the results of compromises between performance/complexity and cost.

General idea of the Invention is based on utilization (and useful features) of the correct, full-fledged APM theory. This theory [formula (2) above] indicates that magnitudes of all components in the PFM modulated signal are proportional to the spectral density of the standardized pulse at frequencies of the corresponding components.

An alternative to the prior art realization of the FM to PFM converter-sampler is possible. In this alternative, the original “sampling (zero-crossing) stream” is not used for generation of short standardized pulses as in prior art (see FIG. 2, numerals 4, 6). Instead, a total zero-crossing stream is divided into 4 physically separated interleaved streams of samples. In other words, four parallel pulse generating circuits are employed, and furthermore these circuits are clocked by the secondary clocks obtained by the logical division of the original zero-crossing sampling clock. This allows use of long standardized pulses of optimal spectral content [optimal g(Ω)], which provides a very efficient “spectral” filtration in the converter-sampler itself. According to Invention, the width of the standardized rectangular pulse is chosen to be equal to the pulse period of the PFM carrier, and the pulse spectrum has zeros at the PFM carrier frequencies. As a result, carrier frequencies are suppressed completely and all surrounding modulation side-bands (due to their proximity to spectral zero) are strongly attenuated in the FM to PFM converter-sampler itself. Thus, at the converter output combination noise is dramatically reduced in value (1.5-2 orders of magnitude) in comparison to the case of short standardized pulses used in the prior art. Then, this already filtered signal is submitted to the final filter-demodulator. In other words, the Invention relieves filter-demodulator from harsh filtering requirements, assigning most of the required filtration to the special FM to PFM converter-sampler-filter. This final filter-demodulator can be of very simple construction and suppresses residual modulation side-bands that are already dramatically reduced in values.

Actually, the Invention introduces a new kind of pulse angle modulation (PPM and PFM) systems, with carrier suppression at the receiver. It dramatically improves system performance, especially for systems with small ratio of carrier frequency to modulation band, as in VTR/VCRs

### BRIEF DESCRIPTION OF DRAWINGS

FIG. 1 illustrates modulation-demodulation processes in the VTR/VCRs of the prior art by timing diagrams.

FIG. 2 is the block diagram of hardware used for signal processing and demodulation during readback cycle in the VTR/VCRs of the prior art.

FIG. 3 illustrates in the frequency domain pulse-frequency modulated signal supplied to the filter-demodulator in the VTR/VCRs of the prior art.

FIG. 4 provides illustrations for the rigorous theories of pulse position modulation (PPM) and pulse frequency modulation (PFM).

FIG. 5 illustrates signal spectrum at the output of the FM to PFM converter-sampler-filter of the present Invention that is supplied to the final filter-demodulator.

FIG. 6 is the block diagram of hardware, which is used for signal processing and demodulation during readback cycle according to the present Invention.

FIG. 7 represents timing diagrams that illustrate operations of the FM to PFM converter-sampler-filter of the present Invention shown in FIG. 6

FIG. 8 is the block diagram of the communication system that utilizes pulse angle (PPM or PFM) modulation-demodulation at both transmitter and receiver ends (no FM to PFM conversion), but still suppresses all carrier harmonics before filter-demodulator, thereby significantly increasing system performance and reducing combination noise.

FIG. 9 illustrates operation of the communication system shown on FIG. 8 by timing diagrams.

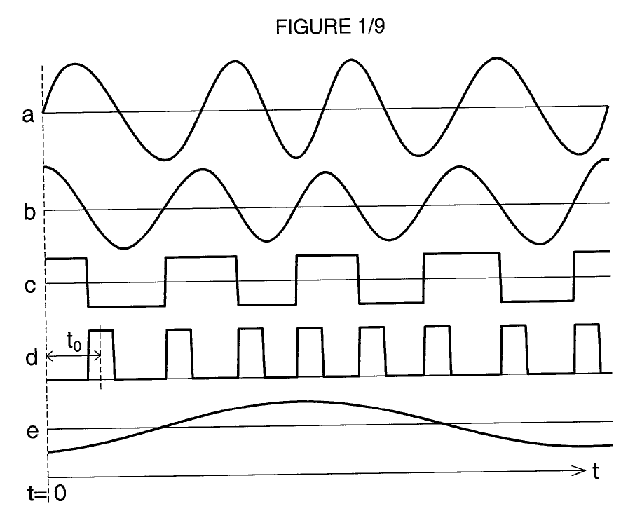

### DETAILED DESCRIPTION OF THE INVENTION

As previously mentioned, the present Invention can not be understood without delving into the PPM and PFM theory. This theory in the form that is adequate for engineering application is not available in English. Some elements of that theory have already been presented in the “background-prior art” section. However, not all aspects and features of the theory have been rigorously proved there. In particular, the fundamental equations (2) and (6) were presented without rigorous proofs, just by patching errors in an incorrect English version of the theory with references to equations of the correct Russian theory. To clarify the subject of Invention and to help in processing patent application a rigorous, self-contained and systematic theory of the PPM and PFM modulations is presented below.

### A. Rigorous Theory of Pulse Position and Pulse Frequency Modulations

An efficient analytic tool for the analysis of pulse modulation of various types is the Method of Deformation, proposed by Ya. D. Shirman. The method is described in the book:

V. I. Siforov, S. A. Drobov, Ya. D. Shirman, N. A. Zheleznov. “Theory of Pulse Radiocommunication.” A monograph in Russian. Classified limited print by Leningrad Military Air—Force Engineering Academy, 1951. Declassified in 1990's.

The method allows one to determine pulse modulation spectra for pulses of rectangular shape. If desired, these “rectangular spectra” can be easily transformed into spectra of the modulated pulse sequence with arbitrary pulse shape, using Method of Shaping Filter, which will be described later.

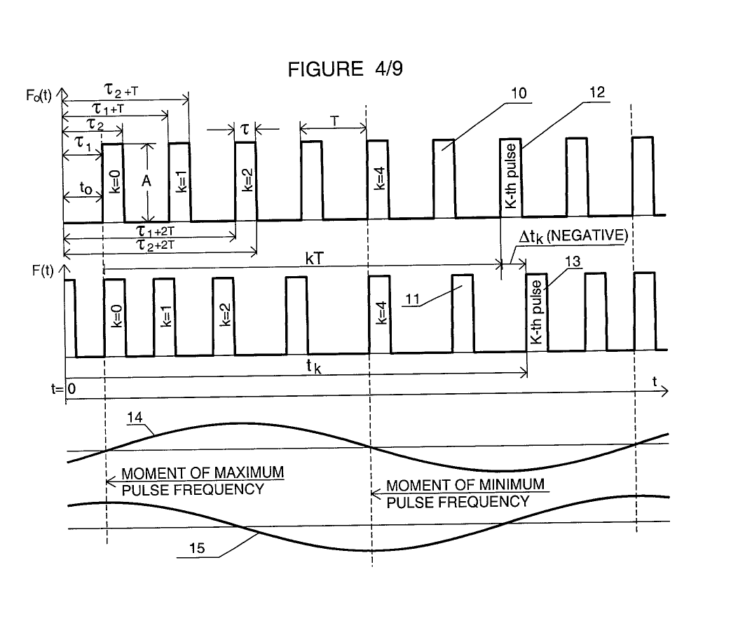

FIG. 4 illustrates two sequences of rectangular pulses: a strictly periodic sequence 10 and the sequence 11 that resulted from the single tone pulse position modulation of the periodic pulse sequence 10.

The defining discrete-time equation for the k^{-th} pulse in the PPM modulated pulse sequence 11 is:

tₖ+Δtₖ=kT+t₀, k=. . . , −2, −1, 0, 1, 2, . . . , (19)

where T, is the period of pulse repetition for the unmodulated pulse sequence and τ is the pulse width (see FIG. 4). The pulses in the sequences are numbered by the letter k; thus tₖ is the moment of generation of the k^{-th} pulse in the modulated pulse sequence and t₀ is the moment of generation of the 0^{-th} pulse in the unmodulated sequence. Δtₖ is the time shift of the k^{-th} pulse due to modulation, The equation (19) is illustrated on FIG. 4 by positions of k^{-th} pulses, numerals 12 and 13.

It should be noted, that the fundamental equation (19), which is the staring point of the PPM modulation theory is not mentioned at all in the English literature on that theory. On the other hand, contrary to Russian theory developed in the 1940s in the “pre-sampling” era, an APM theory in English (H. E. Rowe. “Signal and Noise in Communication Systems.”, D. Van Nostrand, Princeton, N.J., 1965), developed in the 1960s, is based on realization that APM systems work and transmit information in the discrete-time sampling mode. Sampling moments correspond to moments of individual pulses. There are two basic types of the PPM (see cited Rowe's book). The first type—modulation with the natural sampling whereby time displacement of the modulated pulse is proportional to the value of modulating function at the moment of pulse occurrence. The second type—modulation with uniform sampling, in which displacement of the modulated pulse is proportional to the value of modulating function at regularly spaced clock times. The case of uniform sampling is not related to the present invention, and will not be considered here.

For the case of natural sampling, for a single-tone (ST) PPM with the frequency Ω and the initial phase θ, the pulse position shift Δtₖ in the k^{-th} cycle is defined for discrete time moments by the transcendental equation:

Δtₖ=Δt·sin(Ωtₖ+θ), (20)

where Δt is the maximal time shift of the ST modulation. The equation (20) is illustrated (in arbitrary vertical scale) on FIG. 4 by numeral 14. Note, that if the time modulated k^{-th} pulse leads the initial unmodulated k^{-th} pulse, the time shift Δtₖ is defined to be positive. A practical hardware that realizes PPM with natural sampling and the equation (20) is described in the cited above Rowe's book.

Two other parameters of the PPM are defined as follows. The depth of modulation α is the ratio of maximal pulse shift to the pulse period. The index of modulation Φ is defined as the depth of modulation multiplied by 2π:

α=Δt/T, (21)

Φ=2πα=2πΔt/T=ωΔt. (22)

To derive exact expression for the single tone PPM let's consider function F₀(t), that describes periodic sequence of rectangular pulses, numeral 10 on FIG. 4:

$${F}_{0} ( t ) = \{ \begin{matrix}A , & \text{if} {τ}_{1} + k T < t < {τ}_{2} + k T , \\ 0 , & \text{if} {τ}_{2} + k T < t < {τ}_{1} + ( k + 1 ) T .\end{matrix} \\ k = … - 2 , - 1 , 0 , 1 , 2 , … , \qquad ( 23 )$$

where A is the pulse amplitude, τ the pulse width, and time moments for the rising and falling edges of the pulses are τ₁ and τ₂ respectively. For any values of τ₁ and τ₂ such that

0<τ₂−τ₁<T, (24)

the function F₀(t) is uniquely defined and its value can be calculated from the Fourier series:

$$\begin{matrix}\begin{matrix}{F}_{0} ( t ) = A \frac{{τ}_{2} - {τ}_{1}}{T} + \\ {\sum }_{m = 1}^{∞} \frac{2 A}{m π} sin \frac{m ω ( {τ}_{2} - {τ}_{1} )}{2} \cdot cos [ m ω ( t - \frac{{τ}_{1} + {τ}_{2}}{2} ) ] ,\end{matrix} \\ \text{or} & ( 25 ) \\ \begin{matrix}{F}_{0} ( t ) = A \frac{{τ}_{2} - {τ}_{1}}{T} + \\ {\sum }_{m = 1}^{∞} \frac{A}{m π} \{ sin [ m ω ( t - {τ}_{1} ) ] - sin [ m ω ( t - {τ}_{2} ) ] \} .\end{matrix} & ( 26 )\end{matrix}$$

If parameters τ₁ and τ₂ are functions of time, but constrain (24) still holds for any period T, then the equation (23) can be generalized for any t value.

$$F ( t ) = \{ \begin{matrix}A , & \text{if} {τ}_{1} ( t ) + k T < t < {τ}_{2} ( t ) + k T , \\ 0 , & \text{if} {τ}_{2} ( t ) + k T < t < {τ}_{1} ( t ) + ( k + 1 ) T .\end{matrix} \qquad ( 27 )$$

A modification of the parameters τ₁ and τ₂ means deformation of the periodic pulse sequence. The corresponding “deformed” equation (26) becomes:

$$\begin{matrix}F ( t ) = A \frac{{τ}_{2} ( t ) - {τ}_{1} ( t )}{T} + \\ {\sum }_{m = 1}^{∞} \frac{A}{m π} \{ sin ( m ω [ t - {τ}_{1} ( t ) ] ) - sin ( m ω [ t - {τ}_{2} ( t ) ] ) \} .\end{matrix} \qquad ( 28 )$$

Thus, the trigonometric series (28) is written as functions of the deforming parameters τ₁ and τ₂. Now, the task is to find explicit expressions for these parameters, and, by substituting these expressions in (28), to find the spectrum of the PPM.

As was already explained, the modulated pulse sequence is completely and uniquely defined by a discrete set of sampling points. Therefore, there is a freedom to assign arbitrary values to the continuous-time functions τ₁(t) and τ₂(t) between sampling points. In other words, it is sufficient to match the continuous-time functions τ₁(t) and τ₂(t) to the values of the real discrete-time modulating function at the sampling moments only.

For rectangular pulses of constant amplitude A, a PPM with a moderate depth, that does not reverse pulse order in the sequence, is described by a rigorous and unambiguous time-domain expression:

$$F ( t ) = \{ \begin{matrix}A , & \text{if} {t}_{k} < t < {t}_{k}^{′} , \\ 0 , & \text{if} {t}_{k}^{′} < t < {t}_{k + 1} ,\end{matrix} \qquad ( 29 )$$

where tₖ and tₖ′ are moments of the beginning and the end of the k^{-th} pulse in sequence, respectively.

To match the real discrete-time modulation (29) to the deformed sequence (27) for the ST PPM one must match in time the beginnings and the ends of the pulses in these two equations. Thus, from matching (29) and (27), one obtains the first two discrete-time equations of PPM for rectangular pulses:

τ₁(tₖ)+kT=tₖ, (30)

τ₂(tₖ′)+kT=tₖ′. (31)

Combining equations (19) and (20) yields the third equation:

tₖ+Δt·sin(Ωtₖ+θ)=kT+t₀. (32)

The condition of constant duration for modulated pulses yields the fourth equation:

tₖ′=tₖ+τ. (33)

Formulas (30)-(33) are the system of transcendental discrete-time nonlinear equations for the discrete functions τ₁(tₖ) and τ₂(tₖ′) This system can be rearranged. From (32):

tₖ=kT+t₀−Δt sin(Ωtₖ+θ). (34)

Substituting in (33) tₖ from (34) yields:

tₖ′=kT+t₀−Δt sin[Ω(tₖ′−τ)+θ]+τ. (35)

From (30): τ₁(tₖ)=tₖ−kT, and substituting tₖ from (34) yields:

τ₁(tₖ)=t₀−Δt sin(Ωtₖ+θ). (36)

From (31): τ₂(tₖ′)=tₖ′−kT , and substituting tₖ ′ from (35) yields:

τ₂(tₖ′)=t₀−Δt sin[Ω(tₖ′−τ)+θ]+τ. (37)

The deformed continuous-time function (27), (28) will match the real discrete time modulation (29) at sampling moments, if modulating functions are defined as:

τ₁(t)=t₀−Δt sin(Ωt+θ), (38)

τ₂(t)=t₀−Δt sin[Ω(t−τ)+θ]+τ. (39)

Substituting (38) and (39) into (28) results in an intermediate expression:

$$\begin{matrix}F ( t ) = \frac{A τ}{T} + \frac{A Δ t}{T} sin ( \frac{Ω τ}{2} ) cos ( Ω t + θ ) + \\ \frac{A}{π} {\sum }_{m = 1}^{∞} \frac{1}{m} \{ sin [ m ω t - m ω {t}_{0} + m ω Δ t sin ( Ω t + θ ) ] - \\ sin [ m ω t - m ω ( {t}_{0} + τ ) + m ω Δ t sin ( Ω t - Ω τ + θ ) ] \} \\ = \frac{A τ}{T} + \frac{A Δ t}{T} sin ( \frac{Ω τ}{2} ) cos ( Ω t + θ ) + \\ \frac{A}{π} {\sum }_{m = 1}^{∞} \frac{1}{m} \{ sin [ {x}_{1} + b sin ( {y}_{1} ) ] - sin [ {x}_{2} + b sin ( {y}_{2} ) ] \} ,\end{matrix} \qquad ( 40 )$$

where b is a constant, and x₁, x₂, y₁, y₂ are functions of time that also contain some constants.

The “two-tiers-sine” blocks in the last line of (40) can be expanded into series using Jacobi-Anger formula of the Bessel function theory [see page 7, formula (26) in monograph “Higher Transcendental Functions”, volume II, A. Erdelyi, Editor. McGraw-Hill, New York, 1953,]:

$${ⅇ}^{j z sin ( y )} = {\sum }_{n = - ∞}^{∞} {J}_{n} ( z ) {ⅇ}^{j n y} , \qquad ( 41 )$$

where j=√−1, and Jₙ(·) is the Bessel function of the first kind with integer index n. However, the equation (41) by itself is not sufficient for the desired expansion. For said expansion one has to multiply equation (41) by the e^{jx}. This yields:

$${ⅇ}^{j [ x + z sin ( y ) ]} = {\sum }_{n = - ∞}^{∞} {J}_{n} ( z ) {ⅇ}^{j ( x + n y )} . \qquad ( 42 )$$

Equating imaginary parts on both sides of (42) yields the desired expansion tool:

$$sin [ x + z sin ( y ) ] = {\sum }_{n = - ∞}^{∞} {J}_{n} ( z ) sin ( x + n y ) . \qquad ( 43 )$$

Thus, using formula (43) and elementary algebraic and trigonometric manipulations results in the final expression for the single-tone PPM of rectangular pulse sequence:

$${F}_{RECT} ( t ) = \frac{A τ}{T} + \frac{2 A Δ t}{T} sin ( \frac{Ω τ}{2} ) cos ( Ω t + {ϕ}_{0 , 1} ) + \frac{2 A}{π} {\sum }_{m = 1}^{∞} {\sum }_{n = - ∞}^{∞} \frac{1}{m} {J}_{n} ( m Φ ) sin ( \frac{{Ω}_{m , n} τ}{2} ) cos ( {Ω}_{m , n} t + {ϕ}_{m , n} ) , \qquad ( 44 )$$

where Φ=ωΔt is the index of modulation, Ω_{m,n}=mω+nΩis the combination frequency, φ_{m,n}=nθ−mωt₀−Ω_{m,n}τ/2, is the combination phase, and τ is the pulse width.

The equation of a single-tone PPM for the sequence of pulses with an arbitrary shape results from invocation of the mentioned earlier Method of Shaping Filter.

The Method works as follows. After the spectrum of a modulated rectangular pulse sequence (with a nominal pulse width τ) has been obtained by the deformation method, one sets Aτ=1 and then takes the limit of the obtained expression when τ→0. This results in a spectrum for a modulated sequence of delta-pulses. Then, one assumes that these delta-pulses excite a linear filter with the impulse response that is equal to the desired pulse shape. In other words, the familiar idea of convolution is evoked and, in the frequency domain, this is equivalent to multiplication of terms in the formula for the sequence of modulated in position delta-pulses by the complex spectrum density of a pulse with desired shape. Thus, formula for PPM with pulses of arbitrary shape is obtained.

Applying this procedure to (44) yields a rigorous expression for the ST PPM with pulses of arbitrary shape:

$${F}_{ARB} ( t ) = \frac{g ( 0 )}{T} + \frac{\vert g ( Ω ) \vert}{T} \cdot Ω \cdot Δ t \cdot cos ( Ω t + {ϕ}_{0 , 1} ) + \frac{1}{π} {\sum }_{m = 1}^{∞} {\sum }_{n = - ∞}^{∞} \vert g ( {Ω}_{m , n} ) \vert \cdot \frac{{Ω}_{m , n}}{m} \cdot {J}_{n} ( m Φ ) cos ( {Ω}_{m , n} t + {ϕ}_{m , n} ) \qquad ( 45 )$$

Notation here is the same as in (44), except that now g(Ω_{m,n}) represents complex spectral density of a pulse at the frequency Ω_{m,n}. Also, the combination phase is expressed as φ_{m,n}=nθ+arg[g(Ω_{m,n})]−mωt₀.

It is easy to see, that equation (45) coincides with equation (6) in the background (prior art) section, where equation (6) was given without rigorous proof.

This finishes rigorous elaboration on pulse position modulation theory.

As has been already rigorously shown in the background (prior art) section, PPM and PFM modulations occur simultaneously, and, for a ST modulation, they have the same magnitude spectrums differing only in phase. These two pulse modulations have been named (similarly as continuous-time frequency and phase modulations) in the prior art by the common term : Pulse Angle Modulation. And, as shown by rigorous derivations in the prior art section, knowing equation (45) for ST PPM, the equation for the ST PFM can be written as:

$${F}_{PFM} ( t ) = \frac{g ( 0 )}{T} + \frac{\vert g ( Ω ) \vert}{T} \cdot ϵ \cdot cos ( Ω t + {ϕ}_{0 , 1} ) + \frac{1}{π} {\sum }_{m = 1}^{∞} {\sum }_{n = - ∞}^{∞} \vert g ( {Ω}_{m , n} ) \vert \cdot \frac{{Ω}_{m , n}}{m} \cdot {J}_{n} ( m \frac{Δ ω}{Ω} ) \cdot cos ( {Ω}_{m , n} t + {ϕ}_{m , n} ) , \qquad ( 46 )$$

where notation is the same as for formula (2), and the combination phase φ_{m,n}=n·(θ−π/2)+arg[g(Ω_{m,n})]−mωt₀′ differs from the combination phase φ_{m,n} in (45) for PPM by an additional term: −nπ/2.

The graph, numeral 15, on FIG. 4 illustrates visually concurrent nature of PPM and PFM modulations and −90° difference in phase between them.

### B. Description of the Preferred Embodiments

The present Invention includes three preferred embodiments:

B1. General method for performance/cost improvements of combined FM/PFM modulation systems.

B2. Hardware that facilitates that improvement: The special converter(-sampler) of FM modulation into PFM modulation that, simultaneously with FM to PFM conversion and sampling of incoming FM signal provides, efficient filtration functions and completely suppresses detrimental carrier harmonics in the resulting PFM signal.

B3. Pulse angle modulation-demodulation system with suppression of detrimental carrier harmonics.

B1. Method of Conversion of Frequency Modulated Signal into Pulse Frequency Modulated Signal with Suppression of Carrier Frequency Components of the Resulting Pulse Frequency Modulation

The invented Method is based on rigorous theory of the pulse angle modulation, which, until recent publications by the present applicant, was not available in English. According to this theory described in the section on prior art [formula (2)], the magnitudes of all components of the pulse angle modulated signal are proportional to the spectral density of the standardized pulse at component's frequency. In the prior art PFM modulation systems used in commercial VTR/VCRs, this feature of the theory was never utilized. As a result, engineering compromises in commercial VTR/VCRs had been made at not optimal level. In particular, filtering blocks were unnecessary complicated, expensive and/or provided poor performance; this affected whole apparatuses.

The invented Method is based on realization of possibility in the conversion of FM to PFM to use standardized pulses that are equal in width to the pulse period of the PFM carrier of the prior art. With utilization of such standardized pulses, pulse spectrum zeros occur at the frequencies of the PFM carrier. As a result, a detrimental combination noise dominated by carrier components of the PFM is dramatically reduced. This dramatically reduces “filtration problems” in VTR/VCRs.

The idea is to use the zero-crossing (sampling) stream in the incoming FM-modulated signal not for the generation of the standardized pulses, as in the prior art, but for the generation of four (secondary) interleaved sampling clocks in four physically separated parallel channels, employing logical divider by four (with four outputs). The divider is driven by the total zero-crossing (sampling) stream in the incoming FM-modulated signal separates this stream into four parallel interleaved sampling streams/channels. These channels can employ long standardized pulses. Then pulse sequences generated in all four channels are summed in the linear summing block. The result of summation is supplied to the final linear filter-demodulator.

The hardware that realizes the described method is described in the next section. Below are the results of simulation that quantitatively confirm statements above.

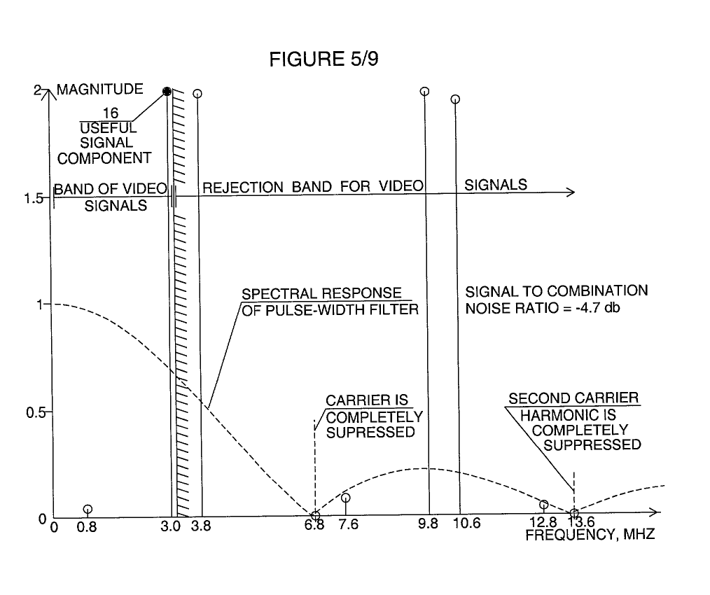

First, a reminding that the magnitude spectrum of the rectangular pulse is given by the formula:

$${g}_{spectr} ( ω τ ) = A \vert \frac{sin ( \frac{ωτ}{2} )}{\frac{ω τ}{2}} \vert , \qquad ( 47 )$$

where A is the pulse area. Variation of the pulse width τ leads to the corresponding variation in the pulse spectrum. The magnitude density for this “Pulse-width-filter” is illustrated on FIG. 5 by the dashed line, assuming that the pulse width is chosen to be equal to the half-period of the original FM-carrier or to the nominal pulse period of the PFM carrier of the prior art. The spectrum (47) has zero phase density in its main lobe. This provides phase-distortion-free filtration in the whole video signal band. On the other hand, as evident from FIG. 5, the PFM carrier and all of its harmonics are completely suppressed.

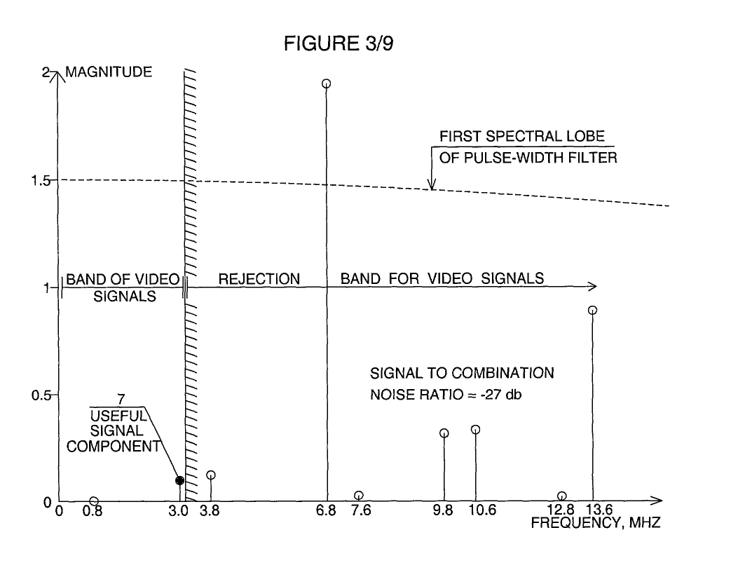

Quantitative benefits of pulse-width filtration can be seen from comparison of results of two signal “processing”. The first is for the signal “processed” in the description of prior art—see FIG. 3 and related text. The second is for the FM-modulated signal with the same modulation parameters as that “processed” in the description of prior art, but with the width of standardized pulses that is equal to the PFM carrier period. Results of the second signal “processing” are summarized on FIG. 5.

For the last case, the useful video signal component is marked by the black bubble, numeral 16. In the prior art (FIG. 3), this useful component (numeral 7) was about 20 times less than the carrier harmonic, and the total signal to combination noise ratio was −27 db. In contrast, after the pulse-width filtration, the same useful component 16 is the largest component presented to the final filter-demodulator, and the total signal to combination noise ratio is −4.7 db. Thus, the improvement in the signal to combination noise ratio is 22 db. Therefore, very simple and inexpensive final filter-demodulator is required to suppress residual side-bands.

B2. Converter of Frequency Modulated Signal into Pulse Frequency Modulated Signal with Suppression of Carrier Frequency Components of the Resulting Pulse Frequency Modulation

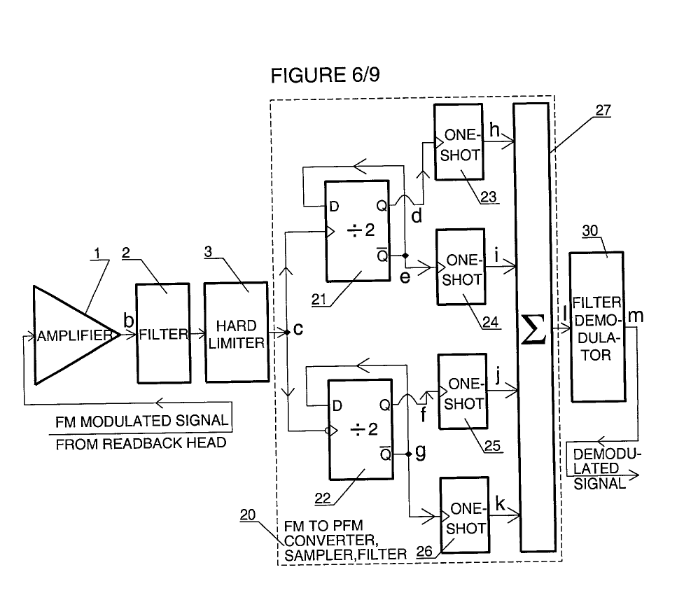

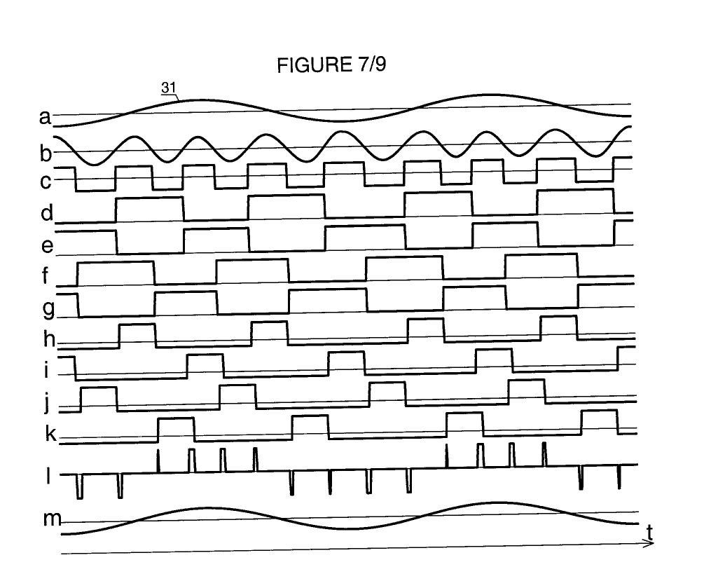

According to the present Invention, FIG. 6 is the conceptual block diagram of hardware for signal processing and demodulation during readback cycle in the VTR/VCRs. FIG. 7 is the timing diagrams, which illustrate operation of hardware shown at FIG. 6. Waveforms, presented on FIG. 7, are marked by letters b to m, which correspond to specific points in hardware, marked on FIG. 6 by the same letters. The exception is the waveform a, numeral 31, on FIG. 7, that illustrates frequency deviation in the FM modulation during the recording cycle. The waveform a is presented to illustrate additionally an intentional (and relatively small in practice) frequency deviation in the incoming raw readback signal, waveform b.

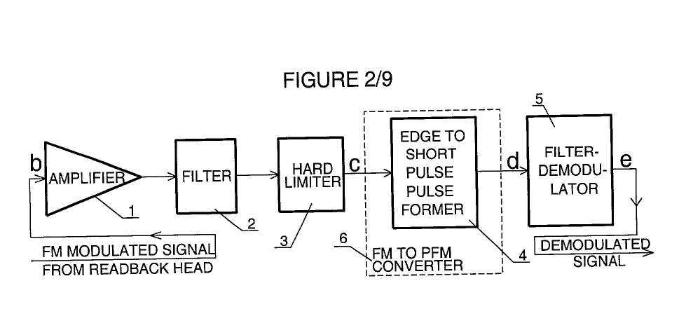

First three blocks of the readback chain shown on FIG. 6 (amplifier 1, filter 2 and hard-limiter 3) are identical to those in the prior art (FIG. 2) and are marked by the same numerals. Operations of these blocks were described in the prior art section.

Output from the hard-limiter 3 s supplied to the FM to PFM converter-sampler-filter 20 of the present Invention, which is shown inside of dashed rectangle. For the sake of brevity, we will refer to this block as C/S/F (converter/sampler/filter). Output from the C/S/F 20 is supplied to the linear filter demodulator 30. The filter-demodulator 30 is very different from that in the prior art (FIG. 2, numeral 5) and is much simpler, because (as will be clear from the detailed explanation below) almost all filtration has already been accomplished in the C/S/F block.

The C/S/F block 20 contains three stages. The first stage is the two parallel dividers by two, 21 and 22 (D-type logical flip-flops) clocked by the edges of the hard-limited signal, waveform C. The divider 21 is clocked by the raising edge; the divider 22—by the falling edge. Dividers 21 and 22 have complimentary outputs, Q and \overline{Q}. Thus, edges of the hard-limited signal, waveform C, together with dividers 21 and 22 generate four sampling clocks at the four divider's outputs (Q and \overline{Q}), see waveforms d to g. In the absence of modulation, these four sampling clocks would be shifted relative to each other by the half period of the FM carrier, or by the full period of the PFM carrier in the prior art (PFM carrier frequencies do not exist in the described C/S/F).

As is obvious from FIGS. 6 and 7, the total “zero-crossing stream” in the hard-limited signal c is physically separated into four interleaved sampling clocks at the divider's outputs.

The second stage of the C/S/F block 20 consists of four identical one-shots (for example, four mono-stable multi-vibrators), numerals 23-26, which are exited by the (rising edges of) sampling clocks, waveforms d-g generated at complimentary outputs Q and \overline{Q} of the dividers 21 and 22. The duration of standardized pulses at the one-shot outputs is set (and controlled) to be exactly half-period of the FM carrier frequency during recording (or one period of carrier frequency of the PFM in the prior art), as illustrated by waveforms h to k. Also, to compensate DC-component in the formula (2), positive levels at the outputs of one-shots in their excited states are set (and controlled) to be 3 times larger than (absolute values of) negative levels at their unexcited states (in the absence of modulation, 25% pulse duty cycle in the one-shot's pulse sequence). The described DC-compensation is illustrated on waveforms h to k by asymmetric position of one-shot's levels relative to the (thin) zero line.

The third stage of the C/S/F 20 consists of the linear summing block 27 that performs summation of pulse signals from the outputs of the one-shots 23-26 and creates signal at the output illustrated waveform l. As evident, despite of long standardized pulses, nonzero values after pulse summation occur only when standardized pulses overlap due to modulation (in the absence of modulation, no pulse overlapping and no signal after summation). As has been already shown in deliberation on “Method” (FIG. 5), the signal at the summing output does not contain carrier components of the PFM modulation; it contains only residual, significantly reduced in values side-bands of that modulation.

The output from the summation block 27 is supplied to the linear filter-demodulator 30. As already mentioned, this filter-demodulator can be of very simple construction. Its task is only to suppress relatively small residual side-bands of the modulation, already significantly reduced in values due to pulse-width filtration in the C/S/F block.

Needless to say, that practical implementation of the described C/S/F block is contemplated inside of a large-scale-integration microelectronic chip. Taking into account huge mass production of commercial VCRs, the relative functional complexity of the described C/S/F represents no problems. From viewpoints of both, manufacturing cost and device performance, replacement of complicated and compromised filters-demodulators of the prior art by the C/S/F blocks and simple filter-demodulators has a lot of sense.

B3. Pulse Angle Modulation-Demodulation System with Suppression of Carrier Harmonics

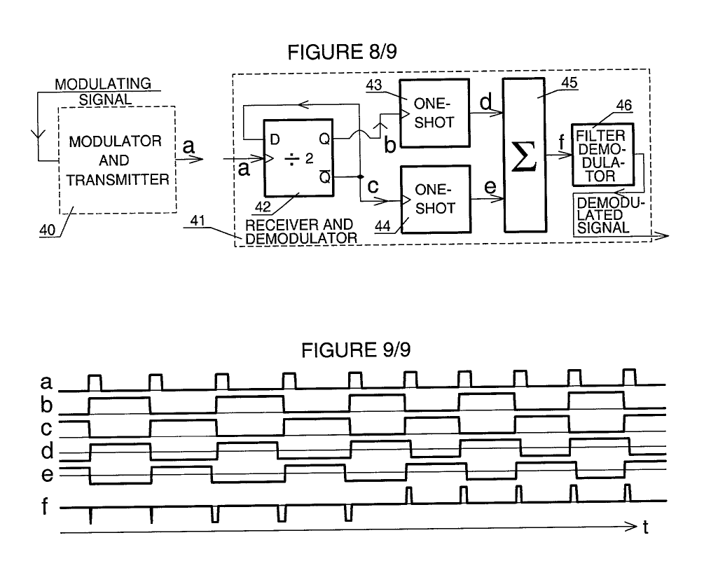

The named above modulation-demodulation system works similarly to the described above C/S/F block. The block diagram of the system is shown on FIG. 8. The timing diagrams of its operations are presented on FIG. 9. The systems includes transmitter part 40 that transmits pulse-angle-modulated signal, waveform a. The receiver part 41 receives transmitted pulses, waveform a and utilizes raising pulse edges for clocking the divider by two 42. The divider 42 has two complimentary outputs Q and \overline{Q}, and, therefore, produces two interleaved sampling clocks, waveforms b and C. The raising edges of these clocks excite two one-shots, 43 and 44. The duration of standardized pulses at the one-shot outputs is set (and controlled) to be exactly one period of the carrier frequency of the transmitted pulse-angle-modulated signal, as illustrated by waveforms d and e. To compensate DC-component in the formulas (2) [or (6)], the positive and negative levels at the outputs of one-shots in their excited and steady states are set (and controlled) to be equal in absolute values (50% pulse duty cycle in absence of modulation). The described DC-compensation is illustrated on waveforms d and e by symmetrical pulse level positions relative to the (thin) zero lines.

The outputs from one-shots, waveforms d and e are summed in the linear summation block 45, that creates output signal illustrated in the time domain by waveform f. As evident, despite of long standardized pulses, non-zero values after pulse summation occur only when standardized pulses overlap due to modulation (in the absence of modulation, no pulse overlapping and no signal after summation).

As has been shown (FIG. 5 and related text) in deliberation of “Method”, the signal at the summing output does not contain carrier components of the pulse-angle modulation—it contains only useful low-frequency information-bearing signal and residual, significantly reduced in values side-bands of that modulation.

The output from the summation block 45 is supplied to the final linear filter-demodulator 46. As already mentioned, this filter-demodulator can be of very simple construction. Its task is only to suppress relatively small residual side-bands of the modulation, already significantly reduced in values due to pulse-width filtration in the one-shots.

What I claim in my invention are:

1. Method of conversion of a frequency modulated signal into the pulse frequency modulated signal with suppression of carrier frequency components of the resulting pulse frequency modulation, comprising of steps:
(a)(i) separation of the total zero-crossing-event-driven sampling clock in the incoming FM-modulated signal into 4 physically separated interleaved secondary clocks with the averaged clock rate in each channel equal to ¼ of the averaged zero-crossing rate in the incoming FM-modulated signal, said task being achieved by employing logical divider by 4 with 4 interleaved outputs, said divider being responsive to the total zero-crossing-event-driven sampling clock in the incoming FM-modulated signal;
(b)(ii)using said 4 interleaved secondary clocks in 4 physically separated channels for generation of 4 parallel and interleaved sequences of rectangular standardized pulses, said standardized pulses having duration of one-half period of the carrier frequency of the incoming FM modulated signal, thus suppressing carrier frequencies and all carrier harmonics of the PFM modulation in each of the 4 interleaved channels;
(c)(iii) summing 4 said interleaved sequences of the generated standardized pulses, thus facilitating absence of carrier frequencies and all carrier harmonics of the PFM modulation at the summation output, before feeding signal at the summation output to the PFM filter-demodulator.

2. Apparatus for conversion of a frequency modulated signal into the pulse frequency modulated signal with suppression of carrier frequency components of the resulting pulse frequency modulation, comprising of:
(a) divider by 4 means responsive to the total zero-crossing-event-driven sampling clock in the incoming FM-modulated signal, said divider by 4 means producing 4 secondary interleaved clocks in 4 physically separated channels, the average clock rate in each channel being equal to ¼ of the average zero-crossing rate in the incoming FM-modulated signal;
(b) one-shot means comprising of 4 one-shot means situated in 4 parallel channels and responsive to the corresponding secondary interleaved clocks to produce interleaved sequences of standardized pulses with duration equal to half-period of the carrier frequency of the incoming FM-modulated signal;
(c) summing means for summation of 4 interleaved sequences of standardized pulses from 4 parallel interleaved channels, output of the summing means being provided to the PFM filter-demodulator.

3. Method of suppression of carrier frequency components at the receiver in the pulse angle modulation system comprising of steps:
(a)(i) separation of the total pulse-event sampling clock in the received pulse angle modulated signal into 2 physically separated interleaved secondary clocks with the averaged clock rate in each channel equal to ½ of the averaged pulse-event rate in the incoming pulse angle modulated signal, said task being achieved by employing logical divider by 2 with 2 interleaved outputs, said divider being responsive to the total pulse-event sampling clock in the incoming pulse-angle modulated signal;
(b)(ii) using said 2 interleaved secondary clocks in 2 physically separated channels for generation of 2 parallel and interleaved sequences of rectangular standardized pulses, said standardized pulses having duration equal to the pulse period of the carrier frequency of the pulse angle modulation, thus suppressing carrier frequencies and all carrier harmonics of the pulse angle modulation in both interleaved channels;
(c)(iii) summing 2 said interleaved sequences of the generated standardized pulses, thus facilitating absence of carrier frequencies and all carrier harmonics of the pulse angle modulation at the summation output before feeding signal at the summation output to the pulse angle filter-demodulator.
